(19) United States
(12) Patent Application Publication
(10) Pub. No.: US 2017/0179324 A1
(43) Pub. Date: Jun. 22, 2017

(54) HIGH-EFFICIENCY LOW-COST SOLAR PANEL WITH PROTECTION CIRCUITRY

(71) Applicant: SolarCity Corporation, San Mateo, CA (US)

(72) Inventors: Bobby Yang, Los Altos Hills, CA (US); Jiunn Benjamin Heng, Los Altos Hills, CA (US)

(73) Assignee: SolarCity Corporation, San Mateo, CA (US)

(21) Appl. No.: 14/971,632

(22) Filed: Dec. 16, 2015

Related U.S. Application Data
(60) Provisional application No. 62/267,181, filed on Dec. 14, 2015.

(51) Int. Cl. H01L 31/05; H01L 31/0443; H01L 31/048

(52) U.S. Cl. CPC H01L 31/0516; H01L 31/0488; H01L 31/0443

(57) ABSTRACT

One embodiment of the invention can provide a solar panel. The solar panel can include a plurality of strings of photovoltaic strips sandwiched between a front cover and a back cover. The strings can be arranged into an array that includes multiple blocks, and a respective block can include a subset of strings that are electrically coupled to each other in parallel. The subset of strings within the block can be coupled to a bypass diode. The multiple blocks can be electrically coupled to each other in series.

### CROSS-REFERENCE TO OTHER APPLICATIONS

This claims the benefit of U.S. Provisional Patent Application No. 62/267,181, Attorney Docket Number P112-1PUS, entitled “HIGH-EFFICIENCY LOW-COST SOLAR PANEL WITH PROTECTION CIRCUITRY,” filed Dec. 14, 2015; the disclosure of which are incorporated herein by reference in their entirety for all purposes.

### FIELD OF THE INVENTION

This is generally related to solar panels. More specifically, this is related to a high-efficiency low-cost solar panel that implements bypass-protection circuits.

### DEFINITIONS

“Solar cell” or “cell” is a photovoltaic structure capable of converting light into electricity. A cell may have any size and any shape, and may be created from a variety of materials. For example, a solar cell may be a photovoltaic structure fabricated on a silicon wafer or one or more thin films on a substrate material (e.g., glass, plastic, or any other material capable of supporting the photovoltaic structure), or a combination thereof.

A “solar cell strip,” “photovoltaic strip,” or “strip” is a portion or segment of a photovoltaic structure, such as a solar cell. A photovoltaic structure may be divided into a number of strips. A strip may have any shape and any size. The width and length of a strip may be the same or different from each other. Strips may be formed by further dividing a previously divided strip.

A “cascade” is a physical arrangement of solar cells or strips that are electrically coupled via electrodes on or near their edges. There are many ways to physically connect adjacent photovoltaic structures. One way is to physically overlap them at or near the edges (e.g., one edge on the positive side and another edge on the negative side) of adjacent structures. This overlapping process is sometimes referred to as “shingling.” Two or more cascading photovoltaic structures or strips can be referred to as a “cascaded string,” or more simply as a “string”.

“Finger lines,” “finger electrodes,” and “fingers” refer to elongated, electrically conductive (e.g., metallic) electrodes of a photovoltaic structure for collecting carriers.

A “busbar,” “bus line,” or “bus electrode” refers to an elongated, electrically conductive (e.g., metallic) electrode of a photovoltaic structure for aggregating current collected by two or more finger lines. A busbar is usually wider than a finger line, and can be deposited or otherwise positioned anywhere on or within the photovoltaic structure. A single photovoltaic structure may have one or more busbars.

A “photovoltaic structure” can refer to a solar cell, a segment, or a solar cell strip. A photovoltaic structure is not limited to a device fabricated by a particular method. For example, a photovoltaic structure can be a crystalline silicon-based solar cell, a thin film solar cell, an amorphous silicon-based solar cell, a poly-crystalline silicon-based solar cell, or a strip thereof.

### BACKGROUND

Advances in photovoltaic technologies, which are used to make solar panels, have helped solar energy gain mass appeal among those wishing to reduce their carbon footprint and decrease their monthly energy costs. However, the panels are typically fabricated manually, which is a time-consuming and error-prone process that makes it costly to mass-produce reliable solar panels.

Solar panels typically include one or more strings of complete photovoltaic structures. Adjacent photovoltaic structures in a string may overlap one another in a cascading arrangement. For example, continuous strings of photovoltaic structures that form a solar panel are described in U.S. patent application Ser. No. 14/510,008, filed Oct. 8, 2014 and entitled “Module Fabrication of Solar Cells with Low Resistivity Electrodes,” the disclosure of which is incorporated herein by reference in its entirety. Producing solar panels with a cascaded cell arrangement can reduce the resistance due to inter-connections between the cells, and can increase the number of photovoltaic structures that can fit into a solar panel.

Moreover, it has been shown that solar panels based on parallelly connected strings of cascaded strips can provide several advantages, including but not limited to: reduced shading, enablement of bifacial operation, and reduced internal resistance. The strips can be created by dividing a complete photovoltaic structure into multiple segments. Detailed descriptions of a solar panel based on cascaded strips can be found in U.S. patent application Ser. No. 14/563,867, attorney Docket No. P67-3NUS, entitled “HIGH EFFICIENCY SOLAR PANEL,” filed Dec. 8, 2014, the disclosure of which is incorporated herein by reference in its entirety for all purposes.

Typical solar panels often implement bypass diodes, which can prevent currents flowing from good photovoltaic structures (photovoltaic structures are well-exposed to sunlight and in normal working condition) to bad photovoltaic structures (photovoltaic structures that are burning out or partially shaded) by providing a current path around the bad cells. Ideally, there would be one bypass diode protecting each photovoltaic structure. However, this will require a great number of bypass diodes per panel and complex electrical connections. In most cases, one bypass diode can be used to protect a group of serially connected strips, which can be a string or a portion of a string.

### SUMMARY

One embodiment of the invention can provide a solar panel. The solar panel can include a plurality of strings of photovoltaic strips sandwiched between a front cover and a back cover. The strings can be arranged into an array that includes multiple blocks, and a respective block can include a subset of strings that can be electrically coupled to each other in parallel. The subset of strings within the block can be coupled to a bypass diode. The multiple blocks can be electrically coupled to each other in series.

In a variation of this embodiment, a respective string can include a plurality of photovoltaic strips arranged in a cascaded manner, and a respective photovoltaic strip can be obtained by dividing a standard photovoltaic structure into multiple segments.

In a further variation, the photovoltaic strip can be obtained by dividing a standard photovoltaic structure into three segments, and accordingly, the block can include three strings.

In a further variation, the string can include 16 or 17 cascaded strips.

In a variation of this embodiment, the array can be a two by two array that includes four blocks of strings, and the solar panel can include four bypass diodes.

In a variation of this embodiment, the multiple blocks can be identical.

In a variation of this embodiment, the multiple blocks can include blocks having strings of different lengths.

In a variation of this embodiment, the solar panel can further include a conductive backsheet positioned between the strings and the back cover.

The conductive backsheet can include a patterned conductive interlayer sandwiched between at least two insulating layers.

In a further variation, electrical couplings among the plurality of strings can be achieved via the patterned conductive interlayer.

In a further variation, electrical coupling between the subset of strings and the bypass diode can be achieved via the patterned conductive interlayer.

### BRIEF DESCRIPTION OF THE FIGURES

FIG. 1A shows an exemplary conductive grid pattern on the front surface of a photovoltaic structure.

FIG. 1B shows an exemplary conductive grid pattern on the back surface of a photovoltaic structure.

FIG. 2A shows a string of cascaded strips.

FIG. 2B shows the side-view of a string of cascaded strips.

FIG. 3 shows an exemplary solar panel layout.

FIG. 4A shows exemplary edge shading scenarios for a solar panel implementing a bypass diode for each branch.

FIG. 4B shows exemplary edge shading scenarios for a solar panel implementing a bypass diode for each row.

FIG. 5 shows an exemplary solar panel, according to an embodiment of the present invention.

FIG. 6 shows exemplary edge shading scenarios for a solar panel, according to an embodiment of the present invention.

FIG. 7 shows an exemplary solar panel, according to an embodiment of the present invention.

FIG. 8 shows an exemplary solar panel with a conductive backsheet, according to an embodiment of the present embodiment.

FIG. 9 shows an exemplary solar panel with a conductive backsheet, according to an embodiment of the present embodiment.

FIG. 10 shows an exemplary fabrication process of a solar panel, according to an embodiment of the present invention.

In the figures, like reference numerals refer to the same figure elements.

### DETAILED DESCRIPTION

The following description is presented to enable any person skilled in the art to make and use the embodiments, and is provided in the context of a particular application and its requirements. Various modifications to the disclosed embodiments will be readily apparent to those skilled in the art, and the general principles defined herein may be applied to other embodiments and applications without departing from the spirit and scope of the present disclosure. Thus, the invention is not limited to the embodiments shown, but is to be accorded the widest scope consistent with the principles and features disclosed herein.

### Overview

Embodiments of the invention can provide a high-efficiency low-cost solar panel with bypass protection circuits. The solar panel can include a number of serially coupled string blocks, with each string block including a number of strings coupled to each other in parallel. Moreover, each string block can be coupled to a bypass diode. Compared with conventional solar panels based on serially connected solar cells, this panel layout can reduce the amount of power being consumed by the internal resistance of the panel. In addition, bypass protecting a string block instead of each individual string can reduce the number of bypass diodes needed for each panel, thus reducing panel fabrication cost.

### Solar Panel Based on Cascaded Strips

As described in U.S. patent application Ser. No. 14/563,867, a solar panel can have multiple (such as 3) strings, each string including cascaded strips, connected in parallel. Such a multiple-parallel-string panel configuration can provide the same output voltage with a reduced internal resistance. In general, a cell can be divided into a number of (e.g., n) strips, and a panel can contain a number of strings (the number of strings can be the same as or different from number of strips in the cell). If a string has the same number of strips as the number of regular photovoltaic structures in a conventional single-string panel, the string can output approximately the same voltage as a conventional panel. Multiple strings can then be connected in parallel to form a panel. If the number of strings in a panel is the same as the number of strips in the cell, the solar panel can output roughly the same current as a conventional panel. On the other hand, the panel's total internal resistance can be a fraction (e.g., 1/n) of the resistance of a string. Therefore, in general, the greater n is, the lower the total internal resistance of the panel is, and the more power one can extract from the panel. However, a tradeoff is that as n increases, the number of connections required to inter-connect the strings also increases, which increases the amount of contact resistance. Also, the greater n is, the more strips a single cell needs to be divided into, which increases the associated production cost and decreases overall reliability due to the larger number of strips used in a single panel.

Another consideration in determining n is the contact resistance between the electrode and the photovoltaic structure on which the electrode is formed. The greater this contact resistance is, the greater n might need to be to reduce effectively the panel's overall internal resistance. Hence, for a particular type of electrode, different values of n might be needed to attain sufficient benefit in reduced total panel internal resistance to offset the increased production cost and reduced reliability. For example, conventional silver-paste or aluminum based electrode may require n to be greater than 4, because process of screen printing and firing silver paste onto a cell does not produce ideal resistance between the electrode and underlying photovoltaic structure. In some embodiments of the present invention, the electrodes, including both the busbars and finger lines, can be fabricated using a combination of physical vapor deposition (PVD) and electroplating of copper as an electrode material. The resulting copper electrode can exhibit lower resistance than an aluminum or screen-printed-silver-paste electrode. Consequently, a smaller n can be used to attain the benefit of reduced panel internal resistance. In some embodiments, n is selected to be three, which is less than the n value generally needed for cells with silver-paste electrodes or other types of electrodes. Correspondingly, two grooves can be scribed on a single cell to allow the cell to be divided to three strips.

In addition to lower contact resistance, electro-plated copper electrodes can also offer better tolerance to micro cracks, which may occur during a cleaving process. Such micro cracks might adversely impact silver-paste-electrode cells. Plated-copper electrode, on the other hand, can preserve the conductivity across the cell surface even if there are micro cracks in the photovoltaic structure. The copper electrode's higher tolerance for micro cracks allows one to use thinner silicon wafers to manufacture cells. As a result, the grooves to be scribed on a cell can be shallower than the grooves scribed on a thicker wafer, which in turn helps increase the throughput of the scribing process. More details on using copper plating to form a low-resistance electrode on a photovoltaic structure are provided in U.S. patent application Ser. No. 13/220,532, attorney Docket No. P59-1NUS, entitled “SOLAR CELL WITH ELECTROPLATED GRID,” filed Aug. 29, 2011, the disclosure of which is incorporated herein by reference in its entirety.

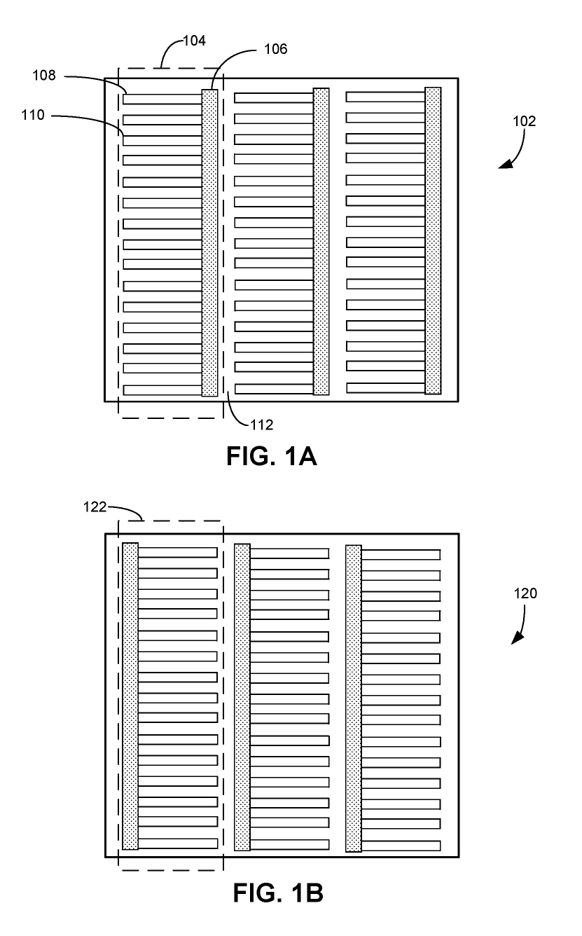

FIG. 1A shows an exemplary grid pattern on the front surface of a photovoltaic structure. In the example shown in FIG. 1A, grid 102 includes three sub-grids, such as sub-grid 104. This three sub-grid configuration allows the photovoltaic structure to be divided into three strips. To enable cascading, each sub-grid needs to have an edge busbar, which can be located either at or near the edge. In the example shown in FIG. 1A, each sub-grid includes an edge busbar (“edge” here refers to the edge of a respective strip) running along the longer edge of the corresponding strip and a plurality of parallel finger lines running in a direction parallel to the shorter edge of the strip. For example, sub-grid 104 can include edge busbar 106, and a plurality of finger lines, such as finger lines 108 and 110. To facilitate the subsequent laser-assisted scribe-and-cleave process, a predefined blank space (i.e., space not covered by electrodes) is inserted between the adjacent sub-grids. For example, blank space 112 is defined to separate sub-grid 104 from its adjacent sub-grid. In some embodiments, the width of the blank space, such as blank space 112, can be between 0.1 mm and 5 mm, preferably between 0.5 mm and 2 mm. There is a tradeoff between a wider space that leads to more tolerant scribing operation and a narrower space that leads to more effective current collection. In a further embodiment, the width of such a blank space can be approximately 1 mm.

FIG. 1B shows an exemplary grid pattern on the back surface of a photovoltaic structure. In the example shown in FIG. 1B, back grid 120 can include three sub-grids, such as sub-grid 122. To enable cascaded and bifacial operation, the back sub-grid may correspond to the front sub-grid. More specifically, the back edge busbar needs to be located at the opposite edge of the frontside edge busbar. In the examples shown in FIGS. 1A and 1B, the front and back sub-grids have similar patterns except that the front and back edge busbars are located adjacent to opposite edges of the strip. In addition, locations of the blank spaces in back conductive grid 120 correspond to locations of the blank spaces in front conductive grid 102, such that the grid lines do not interfere with the subsequent scribe-and-cleave process. In practice, the finger line patterns on the front and back side of the photovoltaic structure may be the same or different.

In the examples shown in FIGS. 1A and 1B, the finger line patterns can include continuous, non-broken loops. For example, as shown in FIG. 1A, finger lines 108 and 110 both include connected loops with rounded corners. This type of “looped” finger line pattern can reduce the likelihood of the finger lines from peeling away from the photovoltaic structure after a long period of usage. Optionally, the sections where parallel lines are joined can be wider than the rest of the finger lines to provide more durability and prevent peeling. Patterns other than the one shown in FIGS. 1A and 1B, such as un-looped straight lines or loops with different shapes, are also possible.

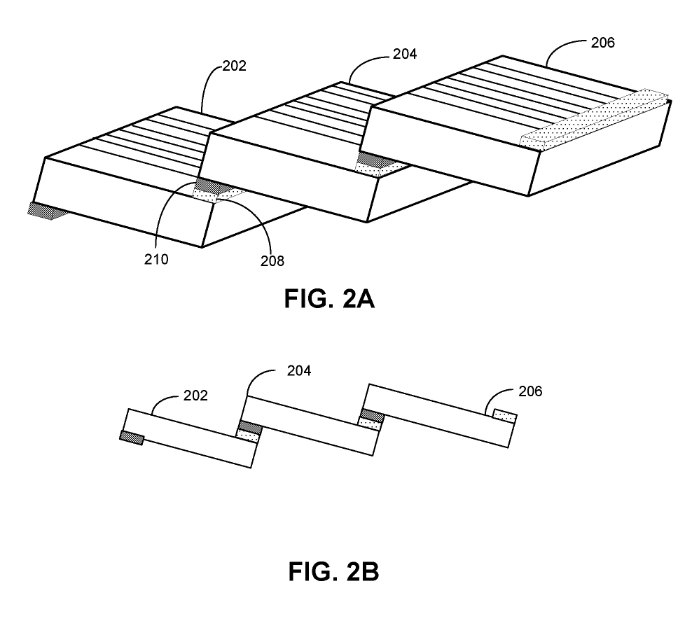

To form a cascaded string, cells or strips (e.g., as a result of a scribing-and-cleaving process applied to a regular square-shaped cell) can be cascaded with their edges overlapped. FIG. 2A shows a string of cascaded strips. In FIG. 2A, strips 202, 204, and 206 are stacked in such a way that strip 206 partially overlaps adjacent strip 204, which also partially overlaps (on an opposite edge) strip 202. Such a string of strips forms a pattern that is similar to roof shingles. Each strip includes top and bottom edge busbars located at opposite edges of the top and bottom surfaces, respectively. Strips 202 and 204 are coupled to each other via an edge busbar 208 located at the top surface of strip 202 and an edge busbar 210 located at the bottom surface of strip 204. To establish electrical coupling, strips 202 and 204 are placed in such a way that bottom edge busbar 210 is placed on top of and in direct contact with top edge busbar 208.

FIG. 2B shows a side view of a string of cascaded strips. In the example shown in FIGS. 2A and 2B, the strips can be part of a 6-inch square-shaped photovoltaic structure, with each strip having a dimension of approximately 2 inches by 6 inches. To reduce shading, the overlapping between adjacent strips should be kept as small as possible. In some embodiments, the single busbars (both at the top and the bottom surfaces) are placed at the very edge of the strip (as shown in FIGS. 2A and 2B). The same cascaded pattern can extend along an entire row of strips to form a serially connected string.

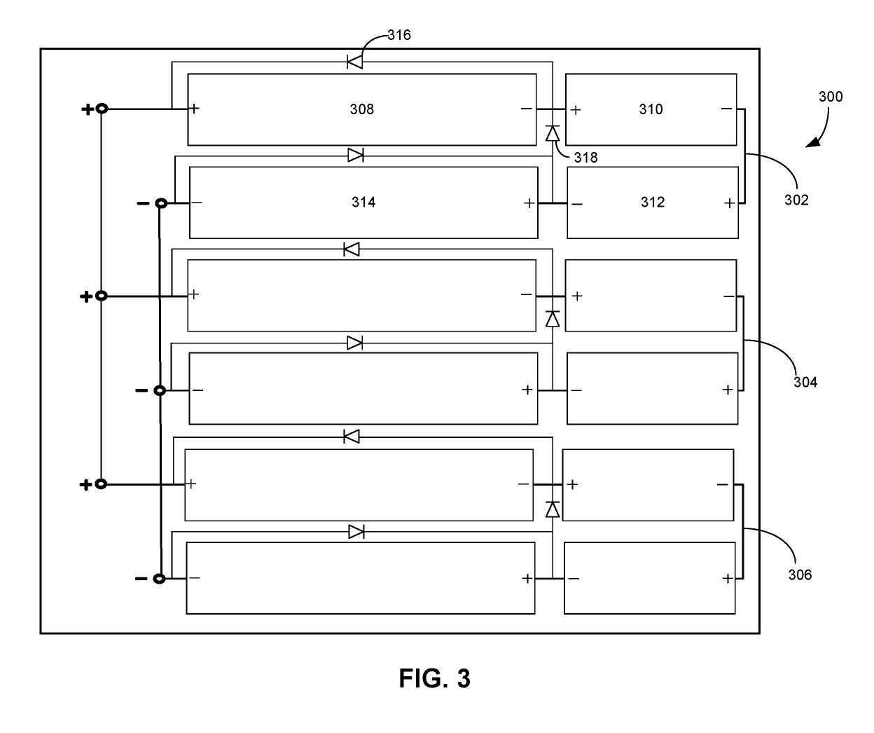

FIG. 3 shows an exemplary solar panel layout. In FIG. 3, solar panel 300 can include three branches coupled to each other in parallel, branches 302, 304, and 306. Each branch can include multiple serially connected strings, and each string can include multiple cascaded strips. For simplicity of illustration, each string is represented using a rectangle, and the strips in the string are not shown in details. In FIG. 3, a branch can include four serially connected strings. For example, branch 302 can include strings 308, 310, 312, and 314. Because the strings are made of cascaded segments of thin Si wafers, it can be difficult to obtain a long string without risking the string being damaged by automated fabrication processes. Hence, multiple strings may be needed to form a single row of the solar panel. In the example shown in FIG. 3, a branch can be arranged to occupy two rows of solar panel 300, with each row including two separate strings. The number of strips in each string can be determined based on the panel size and/or limitations of the fabrication. In some embodiments, each row can include a longer string and a short string. In FIG. 3, longer string 308 may include 18 cascaded strips, and shorter string 310 may include 15 cascaded strips. Considering that a strip may be ⅓ of a photovoltaic structure of a standard size (as shown in FIGS. 1A and 1B), the output voltage and current of panel 300 can be comparable to a conventional panel with 66 serially connected photovoltaic structures of the standard size.

Solar panel 300 can also include multiple bypass diodes, each coupled to one or more strings to provide bypass protection to the one or more strings. For example, bypass diode 316 can be coupled to string 308, and bypass diode 318 can be coupled to strings 310 and 312. Overall, solar panel 300 can include up to 9 bypass diodes.

### High-Efficiency Low-Cost Solar Panel

The solar panel layout shown FIG. 3 can provide various advantages over conventional serial panels. The parallel connection among the branches can lower the overall internal resistance of the panel, and can lead to higher energy output, because the reduced resistance consumes a smaller portion of the photo-generated energy. Moreover, the strategically placed bypass diodes can protect various portions of the panel, in events of a particular portion of the panel being shaded or covered with debris. However, there are still shortcomings associated with this approach for panel layout.

One major problem facing this panel layout is that coupling the 9 bypass diodes to the various strings can still require relative complex wirings. Moreover, the cost of the diodes themselves can significantly impact the cost of the panel. One cost-reduction approach is to reduce the number of diodes coupled to each branch. For example, instead of using three diodes for each branch, as shown in FIG. 3, one can use a single diode for each branch. Alternatively, a single diode can be used for each row of the panel.

However, simply reducing the number of bypass diodes without modifying the panel layout can lead to a different problem. More specifically, when the number of diodes is reduced, edge shading (which can be a common situation for panel arrays) can result in significant power losses.

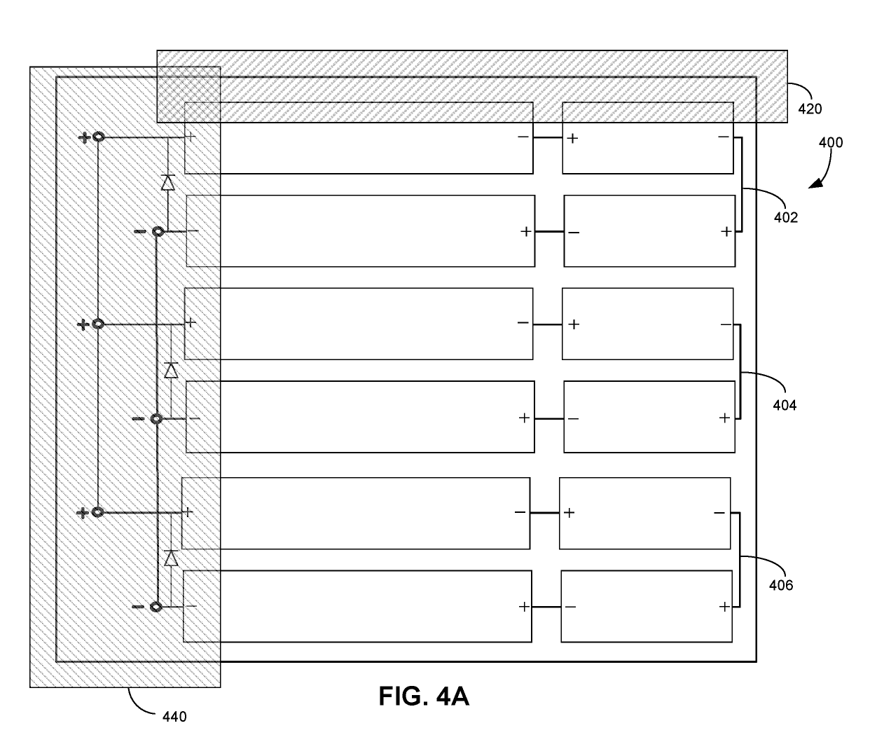

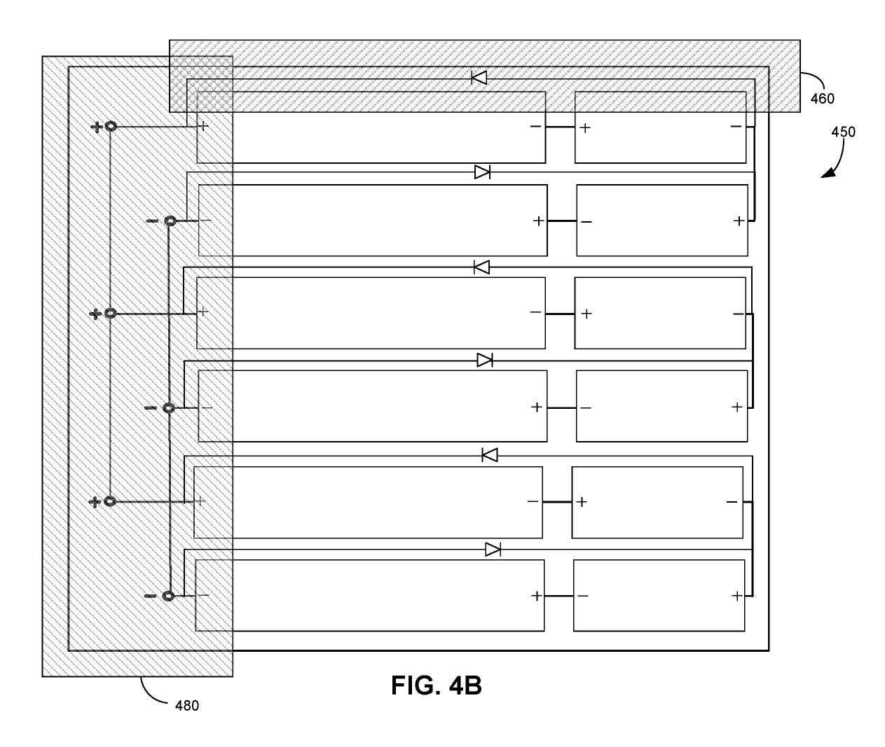

FIG. 4A shows exemplary edge shading scenarios for a solar panel implementing a bypass diode for each branch. In FIG. 4A, solar panel 400 include three parallelly connected branches, branches 402, 404, and 406. Each branch can be coupled to a bypass diode. Panel 400 can include three bypass diodes in total. In FIG. 4A, solar panel 400 is shown to be edge-shaded in two different ways. In one scenario, the longer edge (or the horizontal edge) of panel 400 is shaded, as indicated by hatched area 420. Because each bypass diode is coupled to an entire branch of strings, a partial shading of any string in the branch can result in the entire branch being bypassed. Accordingly, although hatched area 420 only shades a portion of the strings in the uppermost row of solar panel 400, this type of edge shading can cause entire branch 402 to be bypassed. This means that, under this edge-shading scenario, one third of solar panel 400 can no longer produce power. On the other hand, when the shorter edge (or the vertical edge) of solar panel 400 is shaded, as indicated by hatched area 440, all branches will be bypassed, and entire solar panel 400 can no longer produce power.

FIG. 4B shows exemplary edge shading scenarios for a solar panel implementing a bypass diode for each row. In FIG. 4B, each row of solar panel 450 can be coupled to a bypass diode. Solar panel 450 can include six bypass diodes in total. When the longer edge of solar panel 450 is shaded, as indicated by hatched area 460, the entire uppermost row of solar panel 450 will be bypassed. This means that one sixth of solar panel 450 can no longer produce power. On the other hand, when the shorter edge of solar panel 450 is shaded, as indicated by hatched area 480, all rows of solar panel 450 will be bypassed, and entire solar panel 450 can no longer produce power.

As one can see from FIG. 4A and 4B, although the number of bypass diodes can be reduced by coupling more strings to each bypass diode, this can lead to severe power loss problems. In the most extreme cases, shadings at a certain edge can result in the entire solar panel being bypassed. Therefore, this cost-reduction approach is not a viable approach.

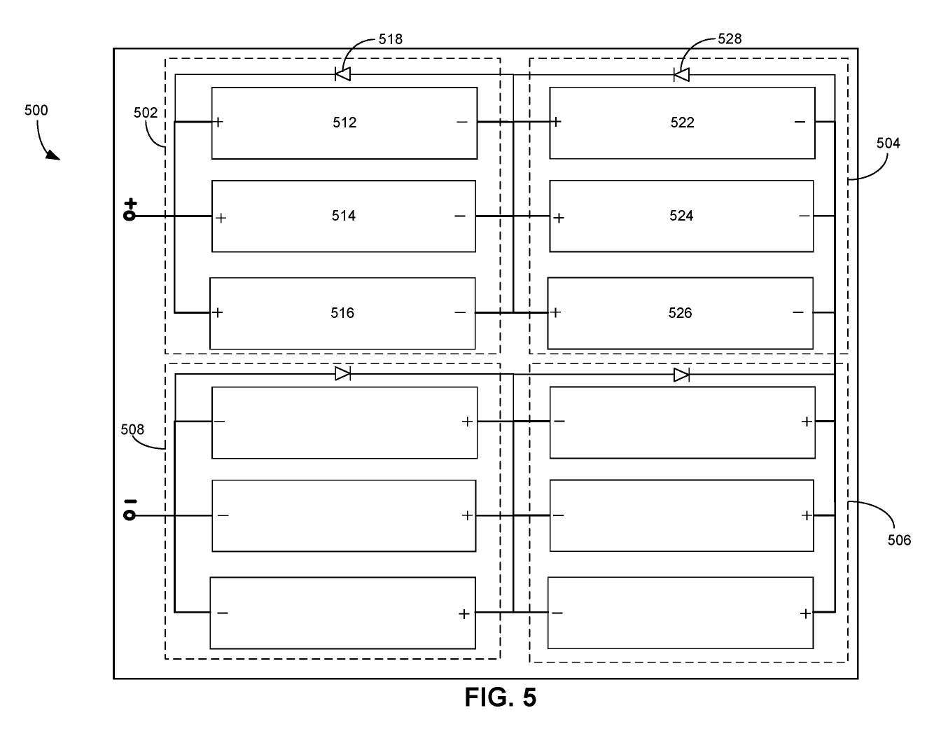

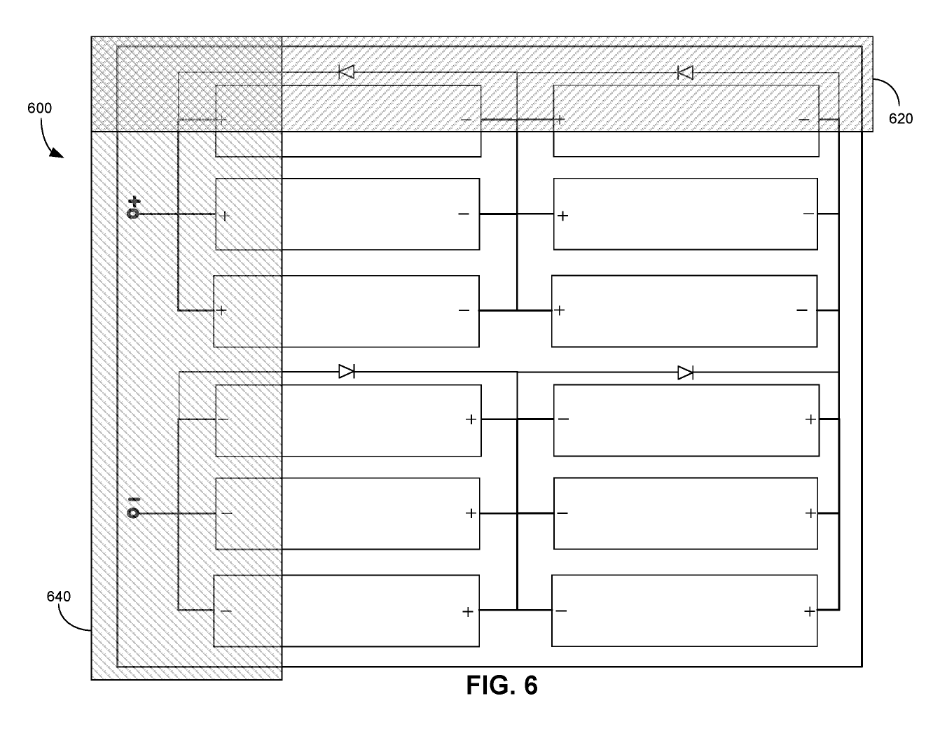

Some embodiments of the present invention provide a novel solar panel that can achieve the cost-reduction goal without facing significant power losses when shaded. More specifically, the novel solar panel can include multiple serially coupled string blocks, with each string block including a number of strings coupled to each other in parallel. FIG. 5 shows an exemplary solar panel, according to an embodiment of the present invention. In FIG. 5, solar panel 500 can include a number of string blocks, such as blocks 502, 504, 506, and 508. Each block can include a number of (e.g., three) parallelly connected strings and a parallelly coupled bypass diode. For example, block 502 can include strings 512, 514, and 516 that are coupled to each other in parallel and bypass diode 518; and block 504 can include parallelly coupled strings 522, 524, and 526 and bypass diode 528. The blocks can be connected to each other in series. To fit into a standard sized panel, in the example shown in FIG. 5, the four blocks can be arranged into a 2 by 2 array with two blocks (e.g., blocks 502 and 504) being placed in the top row and two blocks (e.g., blocks 506 and 508) in the bottom row.

In the example shown in FIG. 3, solar panel 300 can include three parallelly connected branches, with each branch including four serially connected strings. On the other hand, in FIG. 5, solar panel 500 can include four serially connected blocks, with each block including three parallelly connected strings. Hence, solar panels 300 and 500 can provide similar current and voltage outputs. Like solar panel 300, the amount of power consumed by the internal resistance of solar panel 500 can be less compared to conventional serial panels.

In some embodiments, the blocks that are connected in series can be identical blocks. More specifically, the strings included in each block can be identical. For examples, strings 512, 514, and 516 can be identical to strings 522, 524, and 516, with each string including the same number of cascaded strips. In alternative embodiments, the blocks can be different, with the strings in different blocks including different number of cascaded strips. In one embodiment, each of the strings in block 502 (e.g., strings 512, 514, and 516) can include 16 strips, and each of the strings in block 504 (e.g., strings 522, 524, and 526) can include 17 strips. Considering that each strip can be obtained by dividing a photovoltaic structure of a standard size into 3 segments, this panel configuration can result in a solar panel that can produce voltage and current outputs similar to a conventional panel with 66 serially connected photovoltaic structures of the standard size. In an alternative embodiment, all strings within solar panel 500 can include 18 cascaded strips. This configuration can result in a solar panel that can produce voltage and current outputs similar to a conventional panel with 72 serially connected photovoltaic structures.

In the example shown in FIG. 5, each string block is coupled to a bypass diode, and the entire panel can include a total of 4 bypass diodes. Compared to the panel shown in FIG. 3 that includes 9 bypass diodes, the current novel panel can use 5 fewer diodes, which can provide a significant cost saving. It worth noting that, although using fewer bypass diodes than conventional panels, this novel panel can still provide better bypass protection than the conventional panels, especially under various edge shading conditions. FIG. 6 shows exemplary edge shading scenarios for a solar panel, according to an embodiment of the present invention.

In FIG. 6, solar panel 600 can include four serially connected blocks arranged into a 2 by 2 array, with each block being coupled to a bypass diode and including three parallelly coupled strings. In FIG. 6, solar panel 600 is shown to be edge-shaded in two different ways. In one scenario, the longer edge of solar panel 600 is shaded, as indicated by hatched area 620. This edge shading can result in both blocks in the top row of panel 600 to be bypassed. In a different scenario, the shorter edge of panel 600 is shaded, as indicated by hatched area 640, resulting in both blocks in the left column of panel 600 to be bypassed. In summary, shading at the panel edges, regardless of which edge being shaded, can result in at most half of solar panel 600 being bypassed. This means that the novel panel design not only can reduce the number of diodes needed, but also can prevent the occurrence of the worst-case scenario, as shown in FIGS. 4A and 4B, where the entire panel can be bypassed in certain edge shading situations.

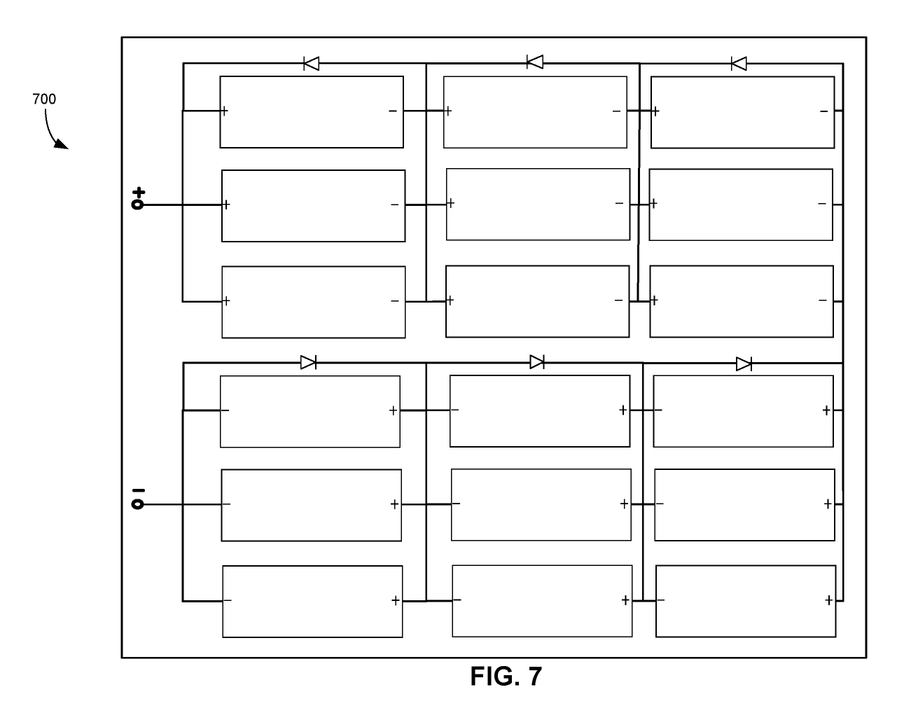

In addition to the 2 by 2 array configuration shown in FIGS. 5 and 6, it can also be possible to have other panel configurations. For example, the solar panel can have fewer or more rows or columns than what's shown in FIGS. 5 and 6. In addition, the number of strips in a string can be different than what's shown in FIGS. 5 and 6. FIG. 7 shows an exemplary solar panel, according to an embodiment of the present invention. In FIG. 7, solar panel 700 can include six string blocks arranged into a 2 by 3 array, with each string block including three strings coupled to each other in parallel. In one embodiment, each string within solar panel 700 can include 11 cascaded strips, and each strip can be ⅓ of a photovoltaic structure of a standard size. This configuration can provide a panel that can produce voltage and current outputs similar to a conventional panel with 66 serially connected photovoltaic structures of the standard size.

In FIG. 7, each string block is coupled to a bypass diode, and solar panel 700 can include a total of 6 bypass diodes. Compared to the example shown in FIG. 6, the additional bypass diodes in solar panel 700 can provide bypass protection at a higher granularity, which can result in better panel performance under the same shaded conditions. In the example shown in FIG. 7, if the shorter edge of solar panel 700 is shaded, only one column (or ⅓) of solar panel 700 will be bypassed. This is an improvement over the scenario shown in FIG. 6, in which half of solar panel 600 will be bypassed if the shorter edge of solar panel 600 is shaded.

As discussed before, to maintain the balance between the desire to lower the total panel internal resistance and the desire to keep the fabrication complexity and cost low, it can be preferred to using strips obtained by dividing standard-sized photovoltaic structures into three segments. However, it is also possible to use strips obtained by dividing the standard-sized photovoltaic structures into more (e.g., four) or fewer (e.g., two) segments. In those situations, to produce outputs that are comparable to conventional serial panels, each block can have the corresponding number of parallelly connected strings. For example, if each strip is ¼ of a standard sized photovoltaic structure, each block should include four parallelly coupled strings.

### Solar Panel with Conductive Backsheet

Although the grid-like panel configurations shown in FIGS. 5 and 7 can allow relative easier fabrications (when compared to convention panels with parallelly coupled branches) due to their symmetrical design, establishing electrical coupling among the strings can still be a challenge using conventional wiring techniques (e.g., by soldering metallic tabs or ribbons onto the busbars). To simplify the electrical coupling among the strings, in some embodiments, the inter-string couplings can be achieved via a conductive backsheet. More specifically, the backsheet (a supporting and insulating layer situated between the strings and the back cover) of the solar panel can include a conductive interlayer sandwiched between multiple insulating layers. The conductive interlayer can be patterned according to the solar panel layout, and desired electrical couplings among the strings can be achieved by establishing conductive paths between busbars of the strings and portions of the conductive interlayer. Detailed descriptions of the conductive backsheet can be found in U.S. patent application Ser. No. 14/924,625, Attorney Docket No. P161-1NUS, entitled “HIGH EFFICIENCY SOLAR PANEL,” filed Oct. 27, 2015, the disclosure of which is incorporated herein by reference in its entirety for all purposes.

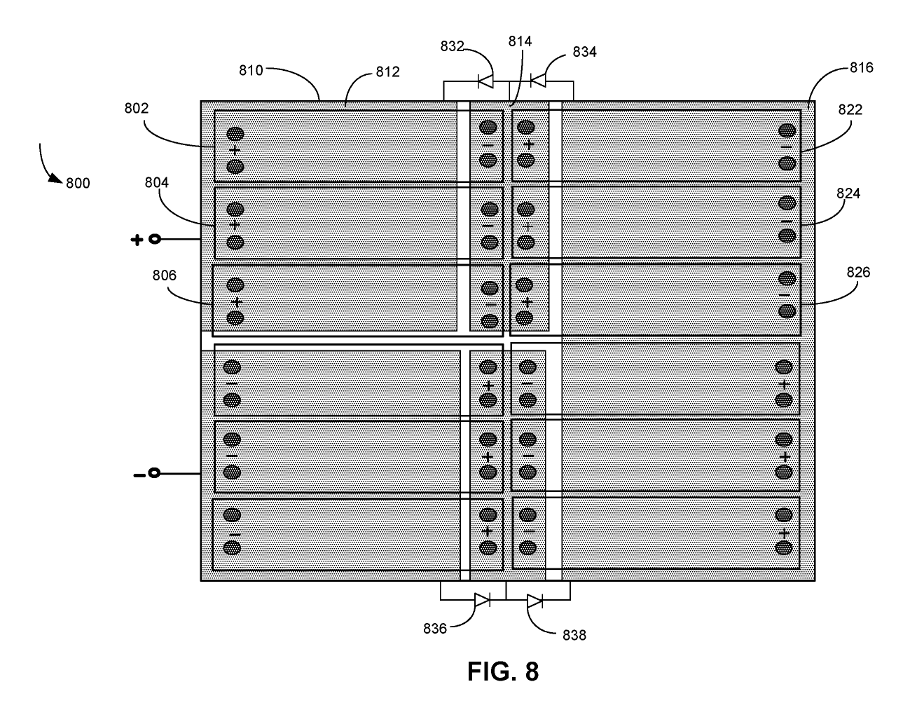

FIG. 8 shows an exemplary solar panel with a conductive backsheet, according to an embodiment of the present embodiment. In FIG. 8, solar panel 800 can include a number of strings (e.g., strings 802 and 804) that are placed on back sheet 810, and can be arranged into a 6 by 2 array, with each of the six rows including two strings. Backsheet 810 can include a patterned conductive interlayer, as indicated by the multiple segregated shaded regions (e.g., regions 812, 814, and 816). For simplicity of illustration, in FIG. 8, the insulations layers of back sheet 810 are not shown, and the strings are shown as being transparent in order to reveal the patterned conductive interlayer underneath.

In FIG. 8, a pair of darkly shaded circles is shown at each end of a string, indicating the electrical coupling between a polarity of the string and a corresponding portion of the conductive interlayer located underneath the string. These circles are for illustration purposes only, and they do not reflect the physical appearance of electrical coupling between the busbar of the strings and the conductive interlayer. In the example shown in FIG. 8, the positive polarity of strings 802, 804, and 806 are coupled to region 812 of the conductive interlayer; and the negative polarity of strings 802, 804, and 806 are coupled to region 814 of the conductive interlayer. This arrangement can result in strings 802, 804, and 806 being coupled to each other in parallel, because each region of the conductive interlayer is an equal-potential plane. Similarly, the positive polarity of strings 822, 824, and 826 are coupled to region 814, and the negative polarity of strings 822, 824, and 826 are coupled to region 816, indicating that strings 822, 824, and 826 are coupled to each other in parallel. Moreover, because the negative polarity of strings 802, 804, and 806 and the positive polarity of strings 822, 824, and 826 are coupled to the same region 814 of the conductive interlayer, these two blocks of strings are serially coupled to each other.

The bottom three rows of the strings in solar panel 800 can also be similarly coupled to corresponding regions of the conductive interlayer. As a result, the strings in each column are coupled to each other in parallel, forming two bottom string blocks, and these two bottom string blocks are coupled to each other in series. Additionally, the bottom two string blocks are serially coupled to the top two string blocks, because the positive polarity of the strings on the right column of the bottom three rows and the negative polarity of the strings on the right column of the top three rows (e.g., strings 822, 824, and 826) are coupled to the same region 816 of the conductive interlayer. As one can see in FIG. 8, the desired electrical coupling among the strings can be readily achieved by simply patterning the conductive backsheet into five segregated regions. This symmetrical design can significantly reduce the fabrication complexity.

Also shown in FIG. 8 are the bypass diodes, e.g., diodes 832, 834, 836, and 838. Each bypass diode can be coupled to a block of strings. For example, bypass diode 832 can be coupled to parallelly coupled strings 802, 804, and 806; and bypass diode 834 can be coupled to parallelly coupled strings 822, 824, and 826. Bypass diodes 836 and 838 are similarly coupled to strings on the bottom left and right string blocks, respectively.

The couplings between the bypass diodes and the string blocks can also be achieved via the conductive interlayer. In FIG. 8, the bypass diodes are shown to be placed above or below the edges of solar panel 800. In practice, the bypass diodes can be placed behind solar panel 800. More specifically, if solar panel 800 is oriented in a way that its front cover faces incident light, the bypass diodes can be placed outside of the panel, behind the back cover. Vias can be created within the back cover and the bottom insulation layer of the backsheet to allow coupling between the bypass diodes and the conductive interlayer of the backsheet. Because the segregated regions of the conductive interlayer are close to each other, it can be possible to arrange the bypass diodes close to each other. In some embodiment, the four bypass diodes can be placed within a same junction box. Such junction boxes can be commercially available off-the-shelf components, thus ensuring a large-scale panel fabrication at a low cost.

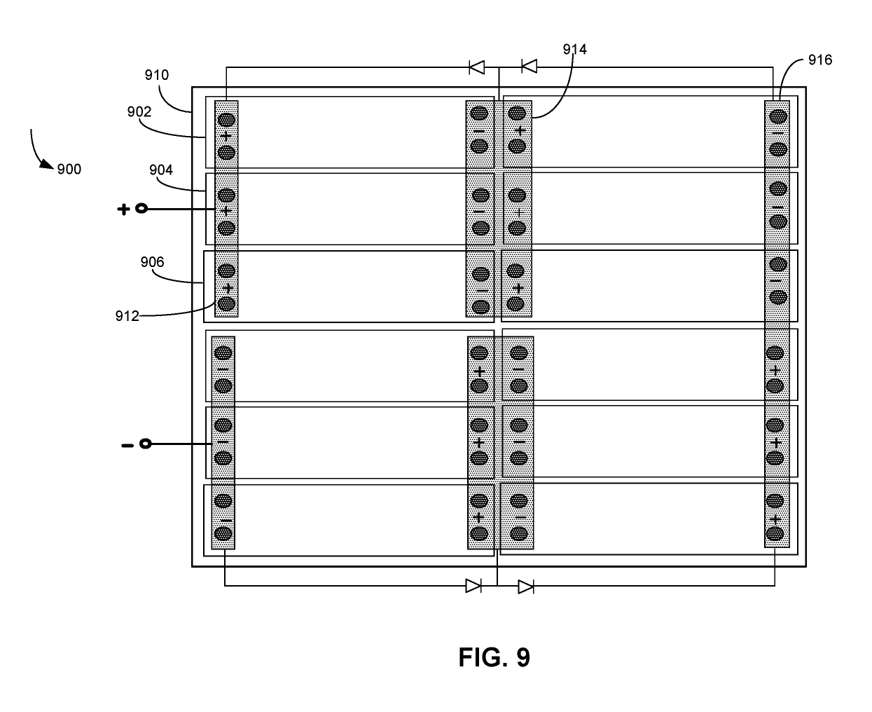

FIG. 9 shows an exemplary solar panel with a conductive backsheet, according to an embodiment of the present embodiment. In FIG. 9, solar panel 900 can be similar to solar panel 800 shown in FIG. 8, and can include serially connected string blocks, with each block including parallelly connected strings. Solar panel 900 can be different from solar panel 800 in the patterning of the conductive interlayer. In solar panel 900, instead of having large continuous conductive regions, the conductive interlayer of backsheet 910 can include small segments of conductive materials. For example, conductive strip 902 can provide electrical coupling among the positive polarities of strings 902, 904, and 906. The size of these conductive segments, such as conductive strip 902, can be designed to be sufficiently small, as long as a low-resistance coupling can be achieved. In some embodiments, the width of conductive strip 910 can be between the width of a busbar to five times the width of the busbar. Strips 914 and 916 can provide similar functions as conductive regions 814 and 816, except that strips 914 and 916 can have smaller areas. Because the conductive interlayer can typically include low-resistance metallic materials, e.g., Cu, keeping the conductive areas small can reduce the cost of the backsheet.

As one can see from FIG. 9, because the conductive strips are now smaller and far away from each other, additional wirings may be needed to connect the bypass diodes to the string blocks. However, such wirings can be placed outside of solar panel 900 and thus do not significantly add to the fabrication complexity.

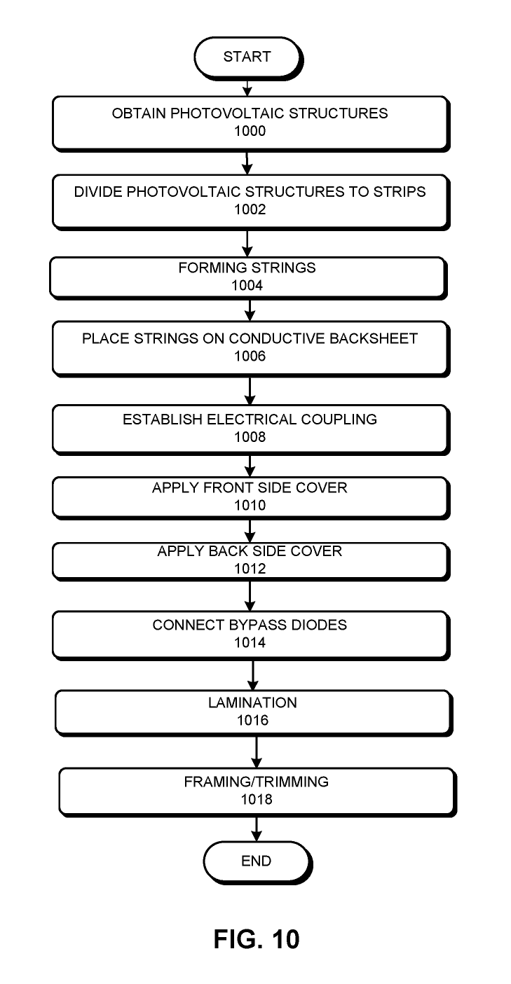

FIG. 10 shows an exemplary fabrication process of a solar panel, according to an embodiment of the present invention. During fabrication, the system can first obtain standard-sized photovoltaic structures (operation 1000), and divide each photovoltaic structure into multiple strips (operation 1002). The system can then form strings of desired length, which can involve arrange a certain number of strips into a cascaded manner (operation 1004). In some embodiments, a string can include 16 or 17 strips.

Subsequently, the strings can be placed onto a conductive backsheet in a desired formation (operation 1006), and electrical couplings among the strings are established (operation 1008). In some embodiments, a subset of strings can be arranged into a string block (e.g., a 3-string block with three strings laid out in parallel), and multiple string blocks can be arranged into an array (e.g., a 2 by 2 array). In some embodiments, establishing electrical couplings can involve applying and curing conductive paste filled into a plurality of vias within the pre-patterned conductive backsheet.

The fabrication process can continue with the application of the front side cover (operation 1010). The panel can then be flipped over for the application of the back side cover (operation 1012). In some embodiments, the back side cover can include through-holes to allow electrical wires to pass through. Bypass diodes, which can be located within a junction box, can then be connected to the various blocks of strings (operation 1014) via those through-holes. The solar panel can then go through the standard lamination (operation 1016) and framing/trimming (operation 1018) processes to complete the fabrication.

The foregoing descriptions of various embodiments have been presented only for purposes of illustration and description. They are not intended to be exhaustive or to limit the invention to the forms disclosed. Accordingly, many modifications and variations will be apparent to practitioners skilled in the art. Additionally, the above disclosure is not intended to limit the invention.

What is claimed is:

1. A solar panel, comprising:
a plurality of strings of photovoltaic strips sandwiched between a front cover and a back cover; and
wherein the strings are arranged into an array that includes multiple blocks, wherein a respective block includes a subset of strings that are electrically coupled to each other in parallel, wherein the subset of strings within the block are coupled to a bypass diode, and wherein the multiple blocks are electrically coupled to each other in series.

2. The solar panel of claim 1, wherein a respective string includes a plurality of photovoltaic strips arranged in a cascaded manner, wherein a respective photovoltaic strip is be obtained by dividing a standard photovoltaic structure into multiple segments.

3. The solar panel of claim 2, wherein the photovoltaic strip is obtained by dividing a standard photovoltaic structure into three segments, and wherein the block includes three strings.

4. The solar panel of claim 3, wherein the string includes 16 or 17 cascaded strips.

5. The solar panel of claim 1, wherein the array is a two by two array that includes four blocks of strings, and wherein the solar panel includes four bypass diodes.

6. The solar panel of claim 1, wherein the multiple blocks are identical.

7. The solar panel of claim 1, wherein the multiple blocks include blocks having strings of different lengths.

8. The solar panel of claim 1, further comprising a conductive backsheet positioned between the strings and the back cover, wherein the conductive backsheet includes a patterned conductive interlayer sandwiched between at least two insulating layers.

9. The solar panel of claim 8, wherein electrical couplings among the plurality of strings are achieved via the patterned conductive interlayer.

10. The solar panel of claim 8, wherein electrical coupling between the subset of strings and the bypass diode is achieved via the patterned conductive interlayer.

11. A method for fabricating a solar panel, comprising:
obtaining a plurality of strings of photovoltaic strips;
arranging the plurality of strings into an array that includes multiple blocks, wherein a respective block includes a subset of strings;
establishing parallel electrical couplings among the subset of strings;
electrically coupling the subset of strings to a bypass diode;
establishing serial electrical couplings among the multiple blocks; and
placing the plurality of strings between a front cover and a back cover.

12. The method of claim 11, wherein obtaining a respective string involves:
obtaining a respective photovoltaic strip by dividing a standard photovoltaic structure into multiple segments; and
arranging a plurality of photovoltaic strips in a cascaded manner.

13. The method of claim 12, wherein obtaining the photovoltaic strip involves dividing a standard photovoltaic structure into three segments, and wherein the block includes three strings.

14. The method of claim 13, wherein obtaining the string involves cascading 16 or 17 photovoltaic strips.

15. The method of claim 11, wherein the array is a two by two array that includes four blocks of strings, and wherein the method further involves electrically coupling the four blocks of strings to four bypass diodes.

16. The method of claim 11, wherein the multiple blocks are identical.

17. The method of claim 11, wherein the multiple blocks include blocks having strings of different lengths.

18. The method of claim 11, further comprising placing the plurality of strings on a conductive backsheet, wherein the conductive backsheet includes a patterned conductive interlayer sandwiched between at least two insulating layers.

19. The method of claim 18, wherein establishing the parallel electrical couplings among the subset of strings and/or establishing the serial electrical couplings among the multiple blocks involve establishing conductive paths between the plurality of strings and the patterned conductive interlayer.

20. The method of claim 18, wherein electrical coupling the subset of strings to the bypass diode involves establishing a conductive path between the bypass diode and the patterned conductive interlayer.
